(19) United States
(12) Patent Application Publication
(10) Pub. No.: US 2012/0313654 A1
(43) Pub. Date: Dec. 13, 2012

(54) Voltage Detection Method and Voltage Detector Circuit

(76) Inventor: Cheng-Hung Chen, Hsinchu County (TW)

(21) Appl. No.: 13/490,443

(22) Filed: Jun. 6, 2012

(30) Foreign Application Priority Data
Jun. 7, 2011 (TW) 100119763

(51) Int. Cl. G01R 19/00; G01R 27/08

(52) U.S. Cl. 324/713; 324/76.11

(57) ABSTRACT

A voltage detection method for detecting a voltage source includes generating a first voltage with a first negative temperature coefficient, wherein the first voltage is related to the voltage source, generating a second voltage with a second negative temperature coefficient, wherein the second voltage is related to the voltage source, and through a comparator to connect the first voltage and the second voltage, for generating a detection result voltage without temperature coefficient according to a voltage difference between the first voltage and the second voltage, and the relationship that the first negative temperature coefficient is equivalent to the second negative temperature coefficient, to perform the voltage detection.

### BACKGROUND OF THE INVENTION

1. Field of the Invention

The present invention relates to a voltage detection method and voltage detector circuit, and more particularly, to voltage detection method and a voltage detector circuit for saving cost.

2. Description of the Prior Art

Due to the characteristics of semiconductors, among many applications, it is needed to design an output current of a current source with temperature coefficient, i.e. the output current varies as environment temperature varies, so as to compensate the non-ideal temperature effect of different circuits.

Please refer to FIG. 1, which is a schematic diagram of a conventional voltage detector circuit 10. The voltage detector circuit 10 detects a voltage source V_{DD} and performs voltage detection through an output voltage V_{OUT} of a comparator 13. As shown in FIG. 1, when a comparison voltage V_{A} connected to a positive terminal of the comparator 13 is greater than a reference voltage V_{BG} connected to the negative terminal of the comparator 13, the comparator 13 outputs a high voltage. When the comparison voltage V_{A} connected to the positive terminal of the comparator 13 is less than the reference voltage V_{BG} connected to the negative terminal of the comparator 13, the comparator 13 outputs a low voltage. When the comparison voltage V_{A} connected to the positive terminal of the comparator 13 is equal to the reference voltage V_{BG} connected to the negative terminal of the comparator 13, the voltage source V_{DD} is equivalent to a detection voltage V_{DD,det} as the voltage detector circuit 10 designed. Wherein, the reference voltage V_{BG} is generated via a bandgap reference generator 11, which comprises a transistor 110, a current source I₁ and a resistor R_{BS}. The transistor 110 can be a bipolar junction transistor (BJT) for outputting the voltage V_{BE}, i.e. the voltage difference between the base and the emitter of the BJT. Noticeably, since the physical characteristics of the BJT, the voltage V_{BE} has a negative temperature coefficient. The output current of the current source I₁ has a positive temperature coefficient, so that at the moment of the current source I₁ on a resistor R_{BS}, a voltage difference ΔV with positive temperature coefficient will be formed within the both terminals of the resistor R_{BS}, to add the ΔV and the voltage V_{BE}, and adjust both temperature coefficients of the ΔV and the V_{BE}, so that the absolute value of the temperature coefficient of the ΔV is equal to that of the V_{BE}, and the reference voltage V_{BG} without temperature coefficient can be acquired.

On the other hand, the comparison voltage V_{A} is generated via cascaded resistors, i.e. resistors R₂ and R₃, performing voltage division to the voltage source V_{DD}. As shown in FIG. 1, the comparison voltage V_{A} is acquired according to following formula:

$${V}_{A} = \frac{{R}_{3}}{{R}_{2} + {R}_{3}} {V}_{DD} \qquad ( 1 )$$

According to above illustrations, when the comparison voltage VA is equal to the reference voltage V_{BG}, the voltage source V_{DD} is equivalent to the detect voltage V_{DD,det} as the voltage detector circuit designed, the V_{DD,det} can be acquired as following formula:

$${V}_{A} = {V}_{BG} ⇒ {V}_{A} = \frac{{R}_{3}}{{R}_{2} + {R}_{3}} {V}_{DD , det} = {V}_{BG} ⇒ {V}_{DD , det} = {V}_{BG} ( 1 + \frac{{R}_{2}}{{R}_{3}} ) \qquad ( 2 )$$

In addition, a total current consumption and a total resistance of the voltage detector circuit 10 can be acquired as following equations:

$$\begin{matrix}{V}_{BG} = {V}_{BE} + {I}_{1} {R}_{BG} ⇒ {I}_{1} = \frac{{V}_{BG} - {V}_{BE}}{{R}_{BG}} , {I}_{R 2} = \frac{{V}_{DD}}{{R}_{2} + {R}_{3}} & ( 3 ) \\ {I}_{total , old} = {I}_{1} + {I}_{R 2} = \frac{{V}_{BG} - {V}_{BE}}{{R}_{BG}} + \frac{{V}_{DD}}{{R}_{2} + {R}_{3}} & ( 4 ) \\ {R}_{total , old} = {R}_{BG} + {R}_{2} + {R}_{3} & ( 5 )\end{matrix}$$

Please further refer to FIG. 2. As shown in FIG. 2, the comparison voltage V_{A} and the reference voltage V_{BG} can be connected to the negative terminal and the positive terminal of the comparator 23, respectively. At the moment that the comparison voltage V_{A} is greater than the reference voltage V_{BG}, the comparator 23 outputs a low voltage. While the comparison voltage V_{A} is less than the reference voltage V_{BG}, the comparator 23 outputs a high voltage. When the comparison voltage V_{A} is equal to the reference voltage V_{BG}, the voltage source V_{DD} is equivalent to the detect voltage V_{DD,det} as the voltage detector circuit 20 designed, wherein the detect voltage V_{DD,det} is equivalent to the detect voltage V_{DD,det} shown in FIG. 1.

However, according to above illustrations, if the conventional bandgap reference generator 11 tends to generate a voltage without temperature coefficient to perform voltage detection, a resistor, i.e. the resistor R_{BS}, for generating the voltage difference ΔV with positive temperature coefficient is further needed to balance the voltage V_{BE} with negative temperature coefficient generated by the transistor 110, so as to generate the reference voltage V_{BG} without temperature coefficient. Above implementation not only increases the resistance of the voltage detector circuit 10, but also wastes the layout area and increases the cost of ICs. Therefore, there is a need to improve the prior art.

### SUMMARY OF THE INVENTION

It is therefore an objective to provide a voltage detection method and a voltage detector circuit which are capable of decreasing the resistance of the voltage detector circuit so as to save cost of ICs.

The present invention discloses a voltage detection method for detecting a voltage source. The voltage detection method includes generating a first voltage with a first negative temperature coefficient, wherein the first voltage is related to the voltage source, generating a second voltage with a second negative temperature coefficient, wherein the second voltage is related to the voltage source, and through a comparator to connect the first voltage and the second voltage, for generating a detection result voltage without temperature coefficient according to a voltage difference between the first voltage and the second voltage, and the relationship that the first negative temperature coefficient is equivalent to the second negative temperature coefficient, to perform the voltage detection.

The present invention further discloses a voltage detector circuit for detecting a voltage source. The voltage detector circuit includes a reference voltage unit for generating a first voltage with a first negative temperature coefficient, wherein the first voltage is related to the voltage source, a comparison voltage unit for generating a second voltage with a second negative temperature coefficient which is equivalent to the first negative temperature coefficient, wherein the second voltage is related to the voltage source, and a comparator connected to the first voltage and the second voltage, for generating a detection result voltage without temperature coefficient according to the voltage difference between the first voltage and the second voltage, and the relationship that the first negative temperature coefficient is equivalent to the second negative temperature coefficient, to perform voltage detection.

The present invention further discloses a voltage detection method for detecting a voltage source. The voltage detection method includes generating a first voltage with a first positive temperature coefficient, wherein the first voltage is related to the voltage source, generating a second voltage with a second positive temperature coefficient which is equivalent to the first positive temperature coefficient, wherein the second voltage is related to the voltage source, and through a comparator connected to the first voltage and the second voltage, for generating a detection result voltage without temperature coefficient according to the voltage difference between the first voltage and the second voltage, and the relationship that the first positive temperature coefficient is equivalent to the second positive temperature coefficient, so as to perform voltage detection.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 2 are schematic diagrams of conventional voltage detector circuits.

FIG. 3 is a schematic diagram of a voltage detection process according to an embodiment of the present invention.

FIGS. 4 and 5 are schematic diagrams of voltage detector circuits according to an embodiment of the present invention.

### DETAILED DESCRIPTION

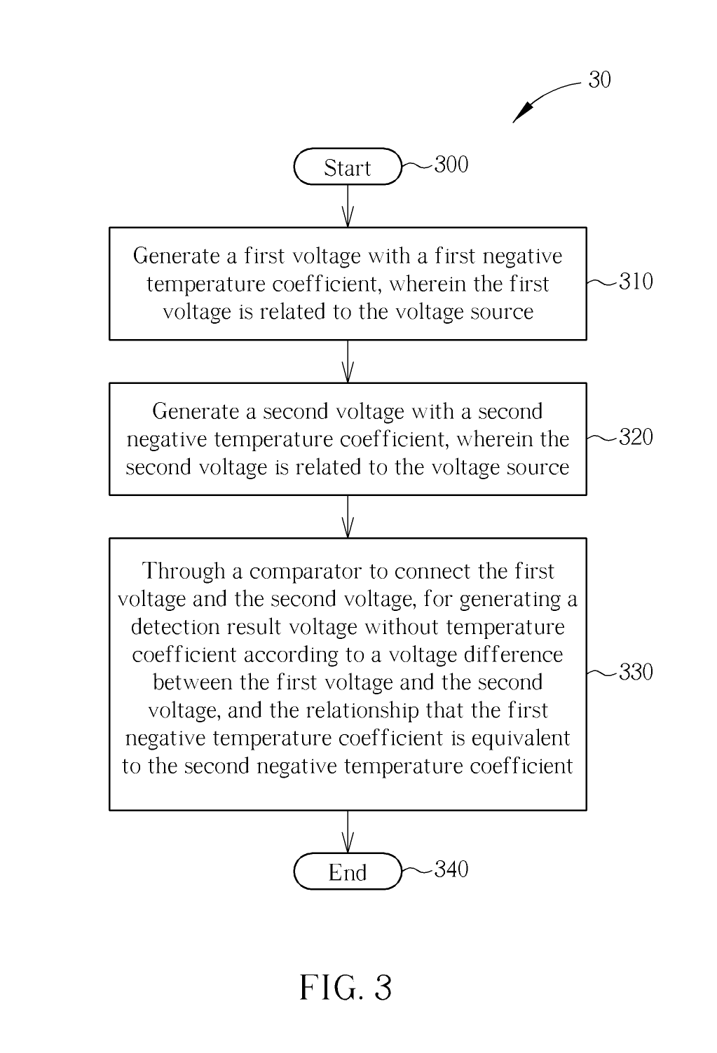

Please refer to FIG. 3, which is a schematic diagram of a voltage detection process 30 according to the embodiment of the present invention. The voltage detection process 30 detects a voltage source and comprises following steps:

Step 300: Start.
step 310: Generate a first voltage with a first negative temperature coefficient, wherein the first voltage is related to the voltage source.

Step 320: Generate a second voltage with a second negative temperature coefficient, wherein the second voltage is related to the voltage source.

Step 330: Through a comparator to connect the first voltage and the second voltage, for generating a detection result voltage without temperature coefficient according to a voltage difference between the first voltage and the second voltage, and the relationship that the first negative temperature coefficient is equivalent to the second negative temperature coefficient.

Step 340: End.

According to the voltage detection process 30, the embodiment of the present invention utilizes the relationship that the comparison voltage and the reference voltage has equivalent temperature coefficients, such that the comparator outputs the detection result voltage without temperature coefficient when the comparator compares the comparison voltage with the reference voltage, so as to achieve voltage detection without temperature coefficient. In other words, when the comparator computes the voltage difference between the positive and negative terminal, i.e. when the comparator compares the comparison voltage with the reference voltage, since the comparison voltage and the reference voltage have equivalent temperature coefficients, the voltage difference between the positive and negative terminal of the comparator offsets the effect of temperature. Therefore, the comparator outputs the detection result voltage which is irrelevant to temperature so as to perform voltage detection. Noticeably, the temperature coefficient which is mentioned can be a positive or negative temperature coefficient, not a zero temperature coefficient.

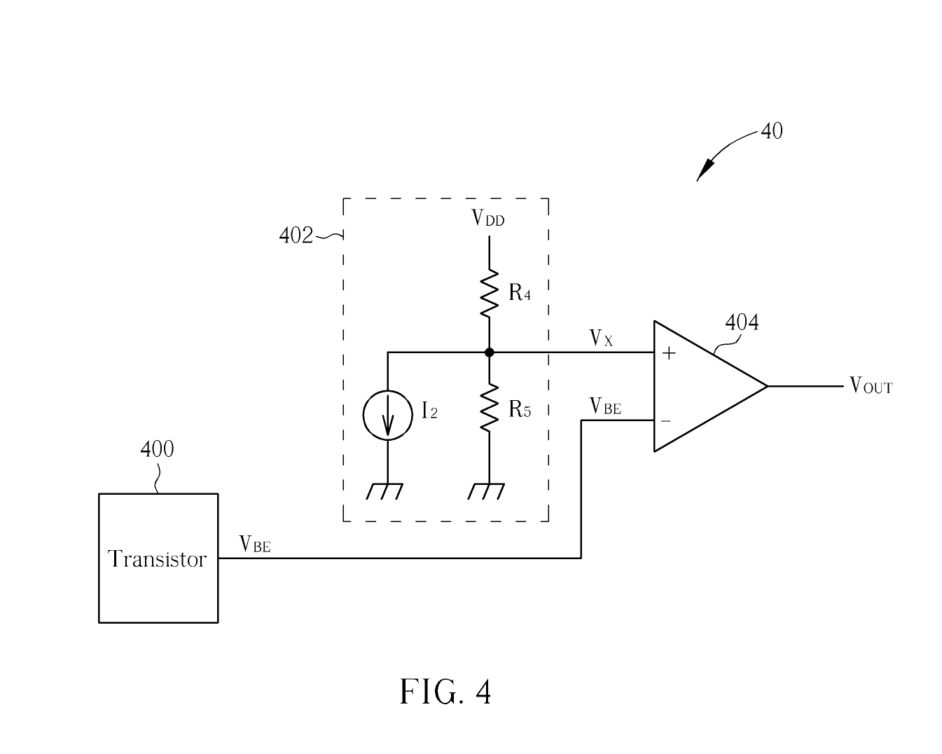

As for the realization of the voltage detection process 30, those skilled in the art would realize the voltage detection process 30 via software or hardware manners. For example, please refer to FIG. 4, which is a schematic diagram of a voltage detector circuit 40 according to the embodiment of the present invention. The voltage detector circuit 40 comprises a reference voltage unit 400, a comparison voltage unit 402 and a comparator 404. The reference voltage unit 400 can be a BJT for generating the reference voltage V_{BE}, i.e. the voltage difference between the base and the emitter, with negative temperature coefficient. The comparison voltage unit 402 comprises a current source I₂ and resistors R₄ and R₅. The current source I₂ outputs the current with positive temperature coefficient, and is connected in parallel to the resistors R₄ and R₅, so that the voltage of the voltage source V_{DD} is divided, and thus generating a comparison voltage Vₓ with negative temperature coefficient. In the present embodiment, the comparison voltage Vₓ and the reference voltage V_{BE} are connected to the positive terminal and the negative terminal of the comparator 404, respectively, for performing voltage detection to the voltage source V_{DD}, and outputting the detection result voltage Vₒᵤₜ through the comparator 404. When the voltage difference between the positive terminal, i.e. the comparison voltage Vₓ, and the negative terminal, i.e. the reference voltage V_{BE}, of the comparator 404 is greater than zero, the comparator 404 outputs a high voltage as a detection result voltage V_{OUT}. When the voltage difference between the positive terminal and the negative terminal of the comparator 404 is less than zero, the comparator 404 outputs a low voltage as the detection result voltage V_{OUT}. When the voltage difference between the positive terminal and the negative terminal of the comparator 404 is equal to zero, the voltage source V_{DD} is equivalent to the detection voltage V_{DD,det} as the voltage detector circuit 40 designed.

In short, the voltage detector circuit 40 generates a comparison voltage with negative temperature coefficient via connecting the current source with positive temperature coefficient in parallel to the cascaded resistors. And connect the comparison voltage and the reference voltage, e.g. the reference voltage generated by the reference voltage unit 400, to the positive and the negative terminals of the comparator, respectively, so as to achieve the voltage detection which is irrelevant to temperature. Detailed description can be obtained by referring to above voltage detection process 30.

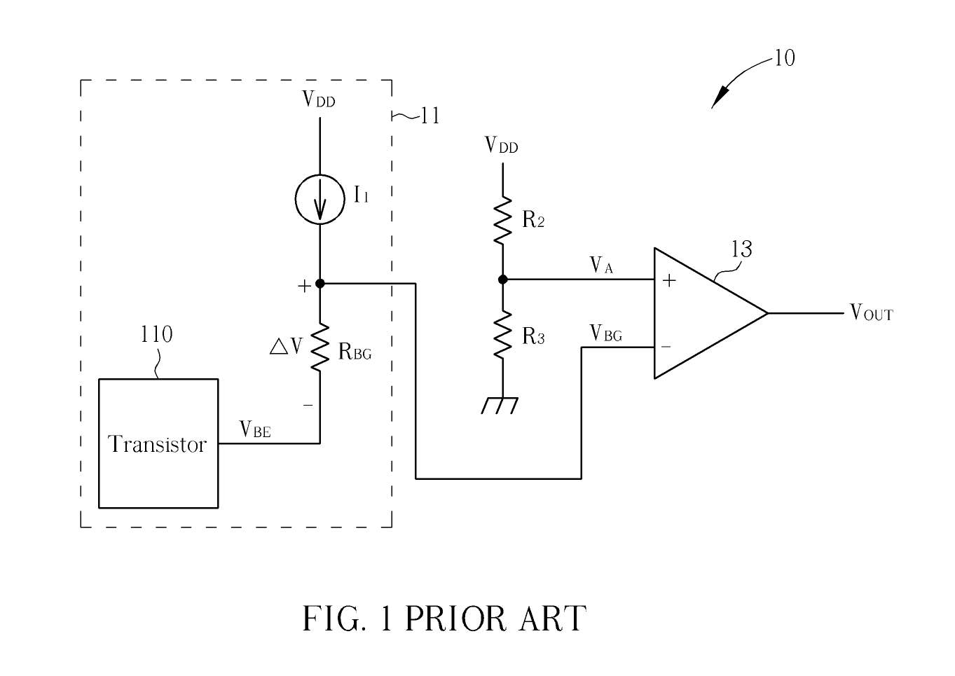

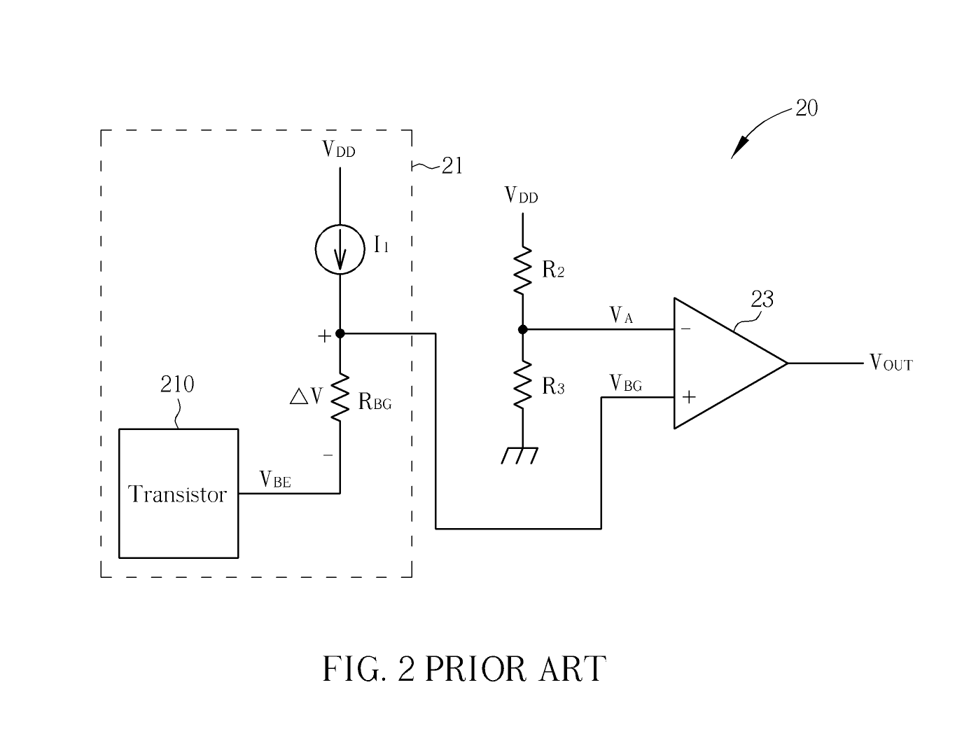

Noticeably, in contrast to the prior art, the present invention does not require the voltage difference with positive temperature for offsetting the voltage with negative temperature to generate the reference voltage without temperature coefficient. Wherein, the voltage difference with positive temperature is generated by extra resistors, e.g. the resistor R_{BS} shown in FIG. 1, and the voltage with negative temperature coefficient is generated by the transistor, e.g. the transistor 110 shown in FIG. 1. Therefore, the embodiment of the present invention decreases the resistance of the conventional voltage detector circuit, thereby lowering cost of ICs.

In addition, the operations of the voltage detector circuit 40 can be obtained according to following equations and FIG. 1, and detailed description as following.

In FIG. 1, the voltage difference V_{comp} between the positive and negative terminals of the comparator can be acquired according to following formulas:

$${V}_{comp} = {V}_{A} - {V}_{BG} = ( \frac{{R}_{3}}{{R}_{2} + {R}_{3}} {V}_{DD} ) - ( {V}_{BE} + {I}_{1} {R}_{BG} ) \qquad ( 6 )$$

Rewritten formula (6), following equations can be acquired:

$$\begin{matrix}{V}_{comp} = ( \frac{{R}_{3}}{{R}_{2} + {R}_{3}} {V}_{DD} - {I}_{1} {R}_{BG} ) - ( {V}_{BE} ) = {V}_{X} - {V}_{BE} & ( 7 ) \\ {V}_{X} = \frac{{R}_{3}}{{R}_{2} + {R}_{3}} {V}_{DD} - {I}_{1} {R}_{BG} & ( 8 )\end{matrix}$$

Substitute

$${I}_{1} = \frac{{V}_{BG} - {V}_{BE}}{{R}_{BG}}$$

of formula (3) into formula (7) knowing that the comparison voltage Vₓ has the temperature coefficient which is equivalent to that of the reference voltage V_{BE}, therefore when the comparison voltage Vₓ and the reference voltage V_{BE} connected to the positive and negative terminals of the comparator, the comparator outputs the detection result voltage without temperature coefficient. As a result, as long as the comparison voltage Vₓ can be synthesized, and connect the comparison voltage Vₓ and the reference voltage V_{BE} to the positive and negative terminals of the comparator, respectively, it can achieve the function of voltage detection irrelevant to temperature as well. According to FIG. 4, the comparison voltage Vₓ, which is synthesized by the voltage detector circuit 40 according to the embodiment of the present invention, can be acquired as following formula:

$${V}_{X} = \frac{{R}_{5}}{{R}_{4} + {R}_{5}} {V}_{DD} - \frac{{R}_{4} {R}_{5}}{{R}_{4} + {R}_{5}} {I}_{2} \qquad ( 9 )$$

Utilize the relationship that the comparison voltage Vₓ of formula (9) is equivalent to the comparison voltage Vₓ of formula (7), it can be acquired:

$$\begin{matrix}{V}_{X} = \frac{{R}_{3}}{{R}_{2} + {R}_{3}} {V}_{DD} - {R}_{BG} {I}_{1} = \frac{{R}_{5}}{{R}_{4} + {R}_{5}} {V}_{DD} - \frac{{R}_{4} {R}_{5}}{{R}_{4} + {R}_{5}} {I}_{2} & ( 10 ) \\ {R}_{4} = \frac{{I}_{1}}{{I}_{2}} {R}_{BG} + \frac{{I}_{1}}{{I}_{2}} \frac{{R}_{2}}{{R}_{3}} {R}_{BG} = \frac{{R}_{BG}}{{I}_{r}} ( 1 + \frac{{R}_{2}}{{R}_{3}} ) & ( 11 ) \\ {R}_{5} = \frac{{I}_{1}}{{I}_{2}} {R}_{BG} + \frac{{I}_{1}}{{I}_{2}} \frac{{R}_{3}}{{R}_{2}} {R}_{BG} = \frac{{R}_{BG}}{{I}_{r}} ( 1 + \frac{{R}_{3}}{{R}_{2}} ) & ( 12 ) \\ {I}_{r} = \frac{{I}_{2}}{{I}_{1}} & ( 13 ) \\ {I}_{total , new} = {I}_{R 4} = \frac{{V}_{DD} + {I}_{2} {R}_{5}}{{R}_{4} + {R}_{5}} & ( 14 )\end{matrix}$$

Substitute formula (11) and (12) into formula (14), the total current consumed by the voltage detector circuit 40 of the present invention can be acquired:

$${I}_{total , new} = {I}_{r} \frac{{V}_{DD} + {I}_{1} {R}_{BG} ( 1 + \frac{{R}_{3}}{{R}_{2}} )}{{R}_{BG} ( 2 + \frac{{R}_{2}}{{R}_{3}} + \frac{{R}_{3}}{{R}_{2}} )} \qquad ( 15 )$$

And then, compared conventional voltage detector circuit, e.g. the voltage detector circuit 10 shown in FIG. 1, with the voltage detector circuit 40 of present invention, the needed total resistance under the situation of same current consumption will be:

$$\begin{matrix}{I}_{total , new} = {I}_{total , old} ⇒ {I}_{r} \frac{{V}_{DD} + {I}_{1} {R}_{BG} ( 1 + \frac{{R}_{3}}{{R}_{2}} )}{{R}_{BG} ( 2 + \frac{{R}_{2}}{{R}_{3}} + \frac{{R}_{3}}{{R}_{2}} )} = \frac{{V}_{BG} - {V}_{BE}}{{R}_{BG}} + \frac{{V}_{DD}}{{R}_{2} + {R}_{3}} & ( 16 ) \\ {I}_{r} = \frac{{R}_{BG} ( 2 + \frac{{R}_{2}}{{R}_{3}} + \frac{{R}_{3}}{{R}_{2}} )}{{V}_{DD} + {I}_{1} {R}_{BG} ( 1 + \frac{{R}_{3}}{{R}_{2}} )} ( \frac{{V}_{BG} - {V}_{BE}}{{R}_{BG}} + \frac{{V}_{DD}}{{R}_{2} + {R}_{3}} ) & ( 17 )\end{matrix}$$

Substitute formula (17) into formula (11) and (12), the resistance of the resistors R₄ and R₅, and the formula will be:

$$\begin{matrix}{R}_{4} = \frac{{R}_{BG}}{{I}_{r}} ( 1 + \frac{{R}_{2}}{{R}_{3}} ) = \frac{{V}_{DD} + {I}_{1} {R}_{BG} ( 1 + \frac{{R}_{3}}{{R}_{2}} )}{( 2 + \frac{{R}_{2}}{{R}_{3}} + \frac{{R}_{3}}{{R}_{2}} ) ( \frac{{V}_{BG} - {V}_{BE}}{{R}_{BG}} + \frac{{V}_{DD}}{{R}_{2} + {R}_{3}} )} ( 1 + \frac{{R}_{2}}{{R}_{3}} ) & ( 18 ) \\ {R}_{5} = \frac{{R}_{BG}}{{I}_{r}} ( 1 + \frac{{R}_{3}}{{R}_{2}} ) = \frac{{V}_{DD} + {I}_{1} {R}_{BG} ( 1 + \frac{{R}_{3}}{{R}_{2}} )}{( 2 + \frac{{R}_{2}}{{R}_{3}} + \frac{{R}_{3}}{{R}_{2}} ) ( \frac{{V}_{BG} - {V}_{BE}}{{R}_{BG}} + \frac{{V}_{DD}}{{R}_{2} + {R}_{3}} )} ( 1 + \frac{{R}_{3}}{{R}_{2}} ) & ( 19 )\end{matrix}$$

Add formula (18) and (19), the needed total resistance of the voltage detector circuit of the present invention can be acquired:

$${R}_{total , new} = {R}_{4} + {R}_{5} = \frac{{V}_{DD} + {I}_{1} {R}_{BG} ( 1 + \frac{{R}_{3}}{{R}_{2}} )}{\frac{{V}_{BG} - {V}_{BE}}{{R}_{BG}} + \frac{{V}_{DD}}{{R}_{2} + {R}_{3}}} \qquad ( 20 )$$

And then, compared the resistance of the conventional voltage detector circuit 10 with that of the voltage detector circuit 40 of the present invention, i.e. divide formula (19) by formula (4), the following formula can be acquired:

$$\frac{{R}_{totoal , new}}{{R}_{total , old}} = \frac{{R}_{4} + {R}_{5}}{{R}_{BG} + {R}_{2} + {R}_{3}} = \frac{{V}_{DD} ( 1 ) + ( {V}_{BG} - {V}_{BE} ) ( 1 + \frac{{R}_{3}}{{R}_{2}} )}{{V}_{DD} ( 1 + \frac{{R}_{BG}}{{R}_{2} + {R}_{3}} ) + ( {V}_{BG} - {V}_{BE} ) ( 1 + \frac{{R}_{2} + {R}_{3}}{{R}_{BG}} )} \qquad ( 21 )$$

When V_{DD}>>(V_{BG}−V_{BE}), formula (21) is less than 1 for good, i.e. the total resistance of the voltage detector circuit 40 is less than that of the voltage detector circuit 10. As a result, the embodiment of the present invention is capable of reducing layout area and saving cost in a condition without increasing current consumption.

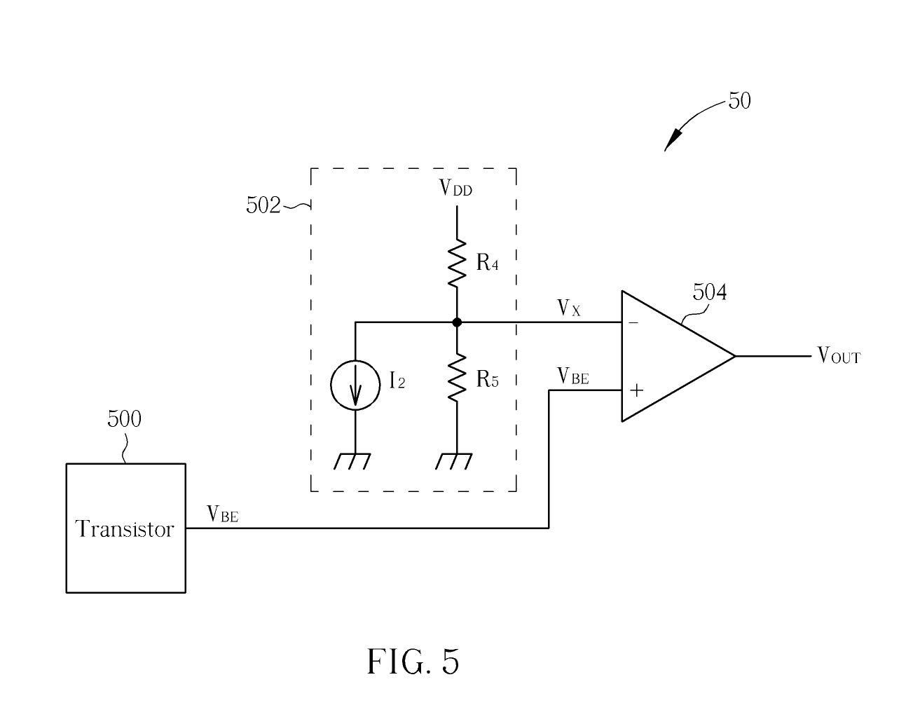

Moreover, please refer to FIG. 5, which is a schematic diagram of a voltage detector circuit 50 according to the embodiment of the present invention. Compared FIG. 5 with FIG. 4, the comparison voltage Vₓ and the reference voltage V_{BE} can connect to the positive terminal and the negative terminal of the comparator 404, may connect to the negative terminal and the positive terminal of the comparator 404 as well, both manners can achieve the effect of the voltage detection. In such a situation, when the voltage difference between the positive terminal, i.e. the reference voltage V_{BE}, and the negative terminal, i.e. the comparison voltage Vₓ, of the comparator 504 is greater than zero, the comparator 504 outputs a high voltage as the detection result voltage Vₒᵤₜ. When the voltage difference between the positive terminal and the negative terminal of the comparator 504 is less than zero, the comparator 504 outputs a low voltage as the detection result voltage Vₒᵤₜ. When the voltage difference between the positive terminal and the negative terminal of the comparator 504 is equal to zero, the voltage source V_{DD} is equivalent to the detect voltage V_{DD,det} as the voltage detector circuit 40 designed.

To sum up, the present invention connects the comparison voltage with equivalent positive/negative temperature coefficient and the reference voltage to the comparator. Since the voltage difference between the comparison voltage and the reference voltage computed by the comparator offsets the effect of temperature, such that the detection result voltage outputted by the comparator is irrelevant to temperature, for voltage detection. In addition, the present invention does not use the resistor for generating the reference voltage without temperature coefficient, and therefore the resistance of the voltage detector circuit of the present invention is less than that of the conventional voltage detector circuit, and thus save cost of ICs.

Those skilled in the art will readily observe that numerous modifications and alterations of the device and method may be made while retaining the teachings of the invention.

What is claimed is:

1. A voltage detection method for detecting a voltage source, the voltage detection method comprises:
generating a first voltage with a first negative temperature coefficient, wherein the first voltage is related to the voltage source;
generating a second voltage with a second negative temperature coefficient, wherein the second voltage is related to the voltage source; and
through a comparator to connect the first voltage and the second voltage, for generating a detection result voltage without temperature coefficient according to a voltage difference between the first voltage and the second voltage, and the relationship that the first negative temperature coefficient is equivalent to the second negative temperature coefficient, to perform the voltage detection.

2. The voltage detection method of claim 1, wherein the step of through a comparator to connect the first voltage and the second voltage, for generating a detection result voltage without temperature coefficient according to a voltage difference between the first voltage and the second voltage, and the relationship that the first negative temperature coefficient is equivalent to the second negative temperature coefficient, to perform the voltage detection comprises:
through a first terminal and a second terminal of the comparator to connect the first voltage and the second voltage, respectively; and
utilizing the voltage difference between the first terminal and the second terminal of the comparator, and the relationship that the first negative temperature coefficient is equivalent to the second negative temperature coefficient, so that the comparator generates the detection result voltage without temperature coefficient.

3. The voltage detection method of claim 2, wherein the step of utilizing the voltage difference between the first terminal and the second terminal of the comparator, and the relationship that the first negative temperature coefficient is equivalent to the second negative temperature coefficient, so that the comparator generates the detection result voltage without temperature coefficient comprises:
if the voltage difference between the first terminal and the second terminal is greater than zero, the detection result voltage is a high voltage;
if the voltage difference between the first terminal and the second terminal is less than zero, the detection result voltage is a low voltage.

4. A voltage detector circuit for detecting a voltage source, the voltage detector circuit comprises:
a reference voltage unit for generating a first voltage with a first negative temperature coefficient, wherein the first voltage is related to the voltage source;
a comparison voltage unit for generating a second voltage with a second negative temperature coefficient which is equivalent to the first negative temperature coefficient, wherein the second voltage is related to the voltage source; and
a comparator connected to the first voltage and the second voltage, for generating a detection result voltage without temperature coefficient according to the voltage difference between the first voltage and the second voltage, and the relationship that the first negative temperature coefficient is equivalent to the second negative temperature coefficient, to perform voltage detection.

5. The voltage detector circuit of claim 4, wherein the comparator comprises:
a first terminal for connecting the first voltage;
a second terminal for connecting the second voltage; and
an output terminal for outputting the detection result voltage, wherein the output voltage is a high voltage if the voltage difference between the first terminal and the second terminal is greater than zero; and the output voltage is a low voltage if the voltage difference between the first terminal and second terminal is less than zero.

6. The voltage detector circuit of claim 4, wherein the reference voltage unit is a transistor for generating the first voltage of the negative temperature coefficient, and the first voltage is the voltage difference between the base and the emitter of the transistor.

7. The voltage detector circuit of claim 4, wherein the comparison voltage unit comprises:
a current source for outputting a current with positive temperature coefficient; and
at least a resistor connected in parallel to the current source for performing voltage division to the voltage source, so as to generate the second voltage with negative temperature coefficient.

8. A voltage detection method for detecting a voltage source, the voltage detection method comprises:
generating a first voltage with a first positive temperature coefficient, wherein the first voltage is related to the voltage source;
generating a second voltage with a second positive temperature coefficient which is equivalent to the first positive temperature coefficient, wherein the second voltage is related to the voltage source; and
through a comparator connected to the first voltage and the second voltage, for generating a detection result voltage without temperature coefficient according to the voltage difference between the first voltage and the second voltage, and the relationship that the first positive temperature coefficient is equivalent to the second positive temperature coefficient, so as to perform voltage detection.

9. The voltage detection method of claim 8, wherein the step of through a comparator connected to the first voltage and the second voltage, for generating a detection result voltage without temperature coefficient according to the voltage difference between the first voltage and the second voltage, and the relationship that the first positive temperature coefficient is equivalent to the second positive temperature coefficient, so as to perform voltage detection comprises:
through a first terminal and a second terminal of the comparator connecting to the first voltage and the second voltage, respectively; and
utilizing the voltage difference between the first terminal and the second terminal of the comparator, and the relationship that the first positive temperature coefficient is equivalent to the second positive temperature coefficient, such that the comparator generates the detection result voltage without temperature coefficient.

10. The voltage detection method of claim 9, wherein the step of utilizing the voltage difference between the first terminal and the second terminal of the comparator, and the relationship that the first positive temperature coefficient is equivalent to the second positive temperature coefficient, such that the comparator generates the detection result voltage without temperature coefficient comprises:
if the voltage difference between the first terminal and second terminal is greater than zero, the detection result voltage is a high voltage;
if the voltage difference between the first terminal and second terminal is less than zero, the detection result voltage is a low voltage.
